(19) United States
(12) Patent Application Publication
(10) Pub. No.: US 2026/0312598 A1
(43) Pub. Date: Oct. 8, 2026

(54) Adaptive Level Crossing adc With Machine Learning

(71) Applicant: Trustees of Tufts College, Medford, MA (US)

(72) Inventor: Sameer SONKUSALE, Lincoln, MA (US)

(73) Assignee: Trustees of Tufts College, Medford,, MA (US)

(21) Appl. No.: 19/478,313

(22) PCT Filed: Apr. 25, 2024
(86) PCT No.: PCT/US2024/026179

§ 371 Date: Oct. 24, 2025

Related U.S. Application Data
(60) Provisional application No. 63/461,722, filed on Apr. 25, 2023.

(51) Int. Cl. H03M 1/12; H03M 1/34

(52) U.S. Cl. CPC H03M 1/124; H03M 1/34

(57) ABSTRACT

A data-acquisition platform an analog input signal includes a converter that provides activity tokens (36) and circuitry connected to receive the activity tokens from the converter. The converter comprises a level-crossing analog-to-digital converter that generates an activity token when the input signal crosses a quantization level. The circuitry comprises either a delay-line analog filter or an adaptation module configured to cause the converter to adaptively change the quantization levels.

WO

### RELATED APPLICATIONS

This application claims the benefit of the Apr. 25, 2023 filing date of U.S. Provisional Application 63/461,722.

### STATEMENT OF GOVERNMENT RIGHTS

This invention was made with government support under grant FA8650-23-2-7308 awarded by the United States Air Force. The government has certain rights in the invention.

### BACKGROUND

It is often useful to carry out processing steps on an analog signal. However, the processing steps available in the analog domain are limited. It is therefore useful to carry out processing steps on an equivalent digital signal. This requires converting the analog signal into a digital signal.

The process of transforming an analog signal into a corresponding digital signal is carried out by an analog-to-digital converter. Many such converters operate by periodically sampling the analog signal. If the analog signal is bandlimited and the sampling rate is fast enough, it is possible to avoid losing any information in the analog signal.

A disadvantage of such converters is that sampling is carried out even if the analog signal is not changing significantly. An alternative approach is to sample the signal only upon occurrence of an event. For example, one can sample the signal when it attains a particular value or changes by a sufficient amount.

### SUMMARY

In one aspect, the invention features apparatus that includes a data-acquisition platform. The data-acquisition platform receives an input signal. This input signal is an analog input signal. Among the data-acquisition platform's constituents are a converter that provides activity tokens and circuitry connected to receive the activity tokens from the converter. The converter includes a level-crossing analog-to-digital converter that generates an activity token when the input signal crosses a quantization level. Embodiments include those in which the circuitry is a filter and those in which it includes an adaptation module. The filter includes a delay-line analog-filter and the adaptation module causes the converter to adaptively change the quantization levels.

Also among the embodiments are those in which the converter includes a first comparator and a second comparator. The first comparator generates a first activity token upon detecting that the input signal has crossed a first quantization level. The second comparator generates a second activity token upon detecting that the input signal has crossed a second quantization level. These first and second activity tokens have opposite polarity.

Some embodiments include correlation circuitry. Examples of correlation circuitry include circuitry determines, based on the activity tokens, whether the input signal matches a reference signal and circuitry that uses the activity tokens to carry out analog cross correlation between the input signal and another signal.

In still other embodiments, the input signal is an electrocardiogram signal. Among these are embodiments in which the data-acquisition platform is configured to identify a QRS complex in the electrocardiogram signal and embodiments in which the data-acquisition platform is configured to identify an arrhythmia in the electrocardiogram signal.

Embodiments further include those in which the input signal includes a combination, or superposition, of plural wireless signals. Among these embodiments are those in which the data-acquisition platform is configured to identify the input signal as being an ultra wideband signal in the combination, those in which the data-acquisition platform is configured to identify the input signal as being a jamming signal in the combination, and those in which the data-acquisition platform is configured to identify the input signal as being a radar signal in the combination.

In still other embodiments, the input signal includes an ultrasonic signal and wherein the data-acquisition platform is configured to identify features in the ultrasonic signal.

In yet other embodiments, the input signal is a combination of acoustic signals, and the data-acquisition platform is configured to identify a particular speaker of one of the acoustic signals.

Also among the embodiments are those in which the circuit comprises a matched filter, tunable analog delay elements, or both.

Still other embodiments include those in which the converter is configured to sample the input signal at a rate that is controlled by the input signal itself.

In another aspect, the invention features a method that includes including receiving an analog input signal, adaptively changing at least one quantization level of a level-crossing analog-to-digital converter, generating an activity token when the input signal crosses the quantization level, and receiving the activity token. In such a method, adaptively changing the at least one quantization level includes using a circuit that is either of a delay-line analog filter or an adaptation module.

Practices of the method include those that further include sampling the analog input signal at a sampling rate that is controlled by the analog input signal.

Also among the practices of the method are those in which adaptively changing the quantization level includes adaptively changing the quantization level based on carrying out real-time adjustment of the quantization levels based on background noise and on a property of the analog input signal.

In still other practices, adaptively changing at least one quantization level includes causing the quantization levels of the level-crossing analog-to-digital converter be time varying quantization levels.

All embodiments described herein are non-abstract in nature. The claims are limited to only non-abstract methods and systems. Coverage of abstract subject is hereby disavowed. As used herein, “non-abstract” is the complement of “abstract” as that term has been defined by the courts of the United States as of the filing date of this application. Any person who construes the claims to cover non-abstract subject matter would therefore be demonstrating an ability to construe the claims in a manner contrary to the specification.

These and other features of the invention will be apparent from the following detailed description and the accompanying claims, in which:

### BRIEF DESCRIPTION OF THE FIGURES

FIG. 1 shows a first embodiment of a data-acquisition platform,

FIG. 2 shows an example in which quantization levels are set based on the slope of the input signal,

FIG. 3 shows a second embodiment of the data-acquisition system in which quantization levels are dynamically adjusted,

FIG. 4 shown an example similar to that shown in FIG. 2 but with dynamically changing quantization levels,

FIG. 5 shows a token generator,

FIG. 6 shows tokens being generated as the input signal crosses quantization levels,

FIG. 7 shows the platform of FIG. 1 being used for correlating an input signal with a reference signal,

FIG. 8 shows an asynchronous delay-line based matched filter,

FIG. 9 shows details of an architecture that adaptively varies quantization levels,

FIG. 10 shows a token generator 24 that dynamically adjusts the bounds of a quantization level;

FIG. 11 shows an implementation of the comparator shown in FIG. 10;

FIG. 12 shows details of the pre-amplifiers shown in FIG. 11;

FIG. 13 shows details of the cross-coupled latch shown in FIG. 11.

FIG. 14 shows details of the current scaling charge pump of FIG. 10 with its charge-pump circuitry coupled to a current source.

FIG. 15 shows details of the comparator shown in FIG. 10;

FIG. 16 shows a preamplifier similar to that shown in FIG. 12;

FIG. 17 shows details of another embodiment of a cross-coupled latch; and

FIG. 18 shows a third amplifier to be used in an embodiment similar to that shown in FIG. 11 but with the output of the second amplifier being provided to the third amplifier. In such an embodiment, the output of the third amplifier is provided to the cross-coupled latch.

### DETAILED DESCRIPTION

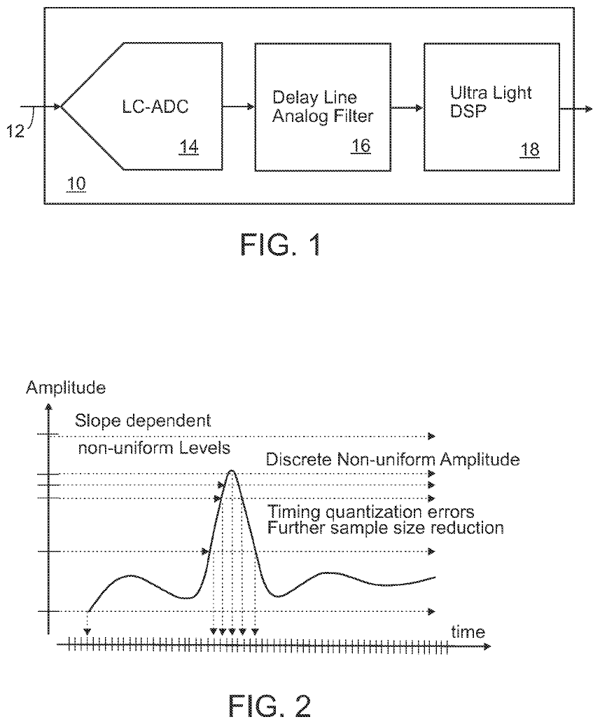

FIG. 1 shows a data-acquisition platform 10 that receives an analog input signal 12. The input signal 12 is a time-varying function having a range that is divided into adjacent intervals.

The boundaries between these intervals are “quantization levels.” As the function's value transitions between two such intervals, it necessary crosses a quantization level.

A level-crossing analog-to-digital converter 14 receives the analog input and outputs an “activity token” whenever the input signal 12 crosses a quantization level.

Each crossing of a quantization level results in an activity token. Each activity token has a polarity that identifies the direction in which it was crossed. A first polarity identifies an upward crossing, i.e., one in which the signals time derivative was positive, and a second polarity identifies a downward crossing, i.e., one in which the input signal's time derivative was negative. The resulting sequence of activity tokens provides considerable information about the analog input. For example, the sequence of activity tokens provides a basis for feature extraction or for correlation with another waveform.

A particular advantage of the level-crossing analog-to-digital converter 14 is that the function itself controls how often sampling occurs. This eliminates the need for a clock and the concomitant possibility of aliasing.

The elimination of aliasing means that there is no need for an anti-aliasing filter. This reduces power requirements, circuit noise, and overall circuit footprint. Although a level-crossing analog-to-digital converter 14 requires a time-to-digital converter, modern time-to-digital converters consume minimal power, require small amounts of space, and achieve picosecond timing resolution.

In the embodiment of FIG. 1, the output of the level-crossing analog-to-digital converter 14 is provided to a filter 16. In some embodiments, the filter 16 is a matched filter that uses analog tunable delay elements. The filter's output is then provided to signal-processing circuitry 18 for further processing.

In some cases, it is useful to set the quantization levels depending on the slopes at various portions of the input signal 12. In the example shown in FIG. 2, the quantization levels are closest together near the peak of the function so that more detail can be acquired in that region of the function's domain. This improves the ability to track a rapidly changing input signal 12 with high dynamic range.

The quantization levels need not be fixed over time. In some cases, it is useful to adjust the quantization levels dynamically.

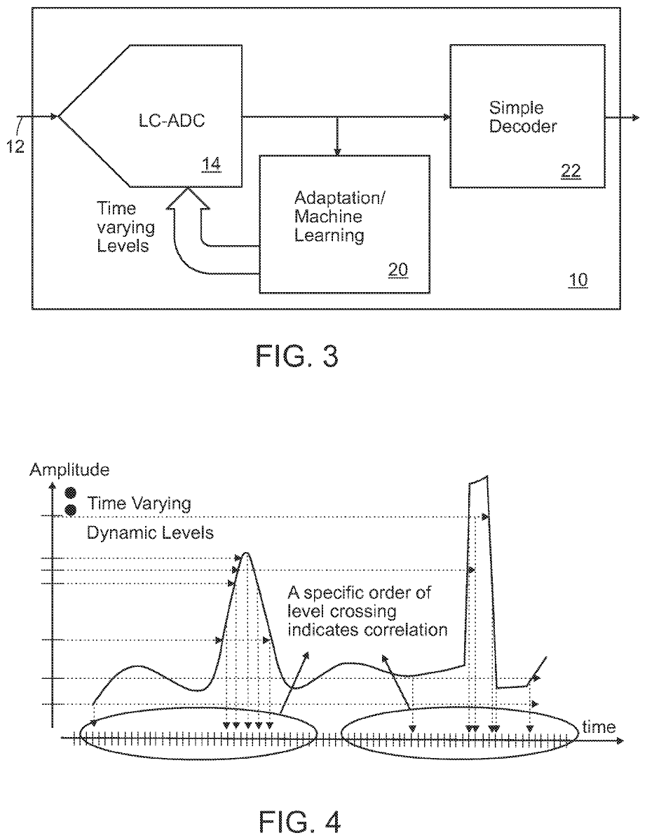

An alternative embodiment, shown in FIG. 3, provides an adaptation module 20 that dynamically adjusts the quantization levels based on information about the input signal 12. In this embodiment, the level-crossing analog-to-digital converter 14 provides its output both to a decoder 22 and to the adaptation module 20. This permits direct analog-to-feature expression and the ability to efficiently perform correlation using the input signal 12.

In some embodiments, the adaptation module 20 carries out a machine-learning procedure. Use of machine learning enables built-in complex waveform tracking and digital calibration to provide system level improvement in dynamic range. In particular, the use of machine learning permits real-time adjustment of quantization levels based on the nature of the waveform, background noise, and other signal conditions.

The omission of a clock provides the data acquisition system with an effective sampling rate limited only by the delay resolution in the underlying hardware. As such, effective sampling ranges on the order of tens of gigahertz become achievable. Moreover, the illustrated architecture is also capable of computing cross-correlation of several template waveforms using the same level-crossing analog-to-digital converter 14.

As noted above, since the levels are precisely known, there is effectively no quantization error in amplitude. However, uncertainty in precisely when the level crossing occurs still exists, as a result of, for example, jitter. This results in quantization noise, albeit in time instead of in amplitude. As a result, the signal-to-noise ratio of the level-crossing analog-to-digital converter 14 depends only on the logarithm of the timer resolution. It does not depend on the actual number of levels. This is different from a conventional N-bit Nyquist analog-to-digital converter, in which the signal-to-noise ratio depends on the logarithm (base two) of the number of quantization levels.

FIG. 4 shows an example in which levels change dynamically in time based on a matching waveform template. A specific sequence of level crossings indicates correlation between the input signal 12 and the template. In this case, a matched filter is optional. In addition, multiple waveform correlation is possible using the same hardware as shown for two waveforms.

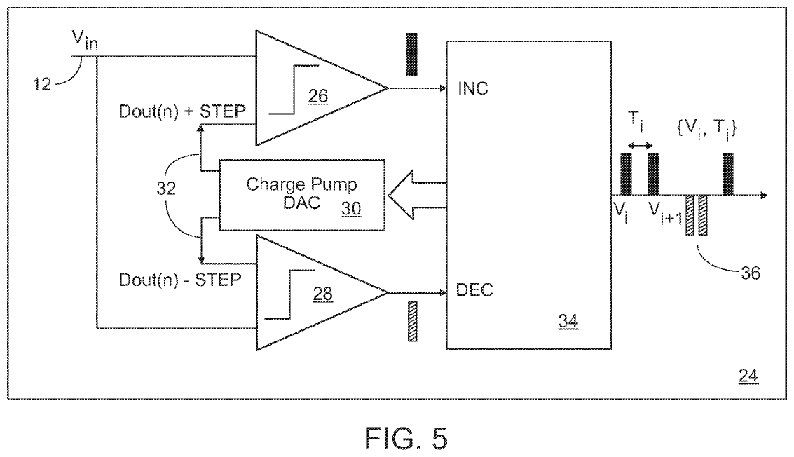

FIG. 5 shows an example of a token generator 24 within the converter 14. The token generator 24 features first and second continuous time comparators 26, 28, each of which receives the input signal 12. A digital-to-analog converter 30 provides the first comparator 26 with a guiding signal 32 that has been incremented by a step and provides the second comparator 28 with the same guiding signal 32 but decremented the same step.

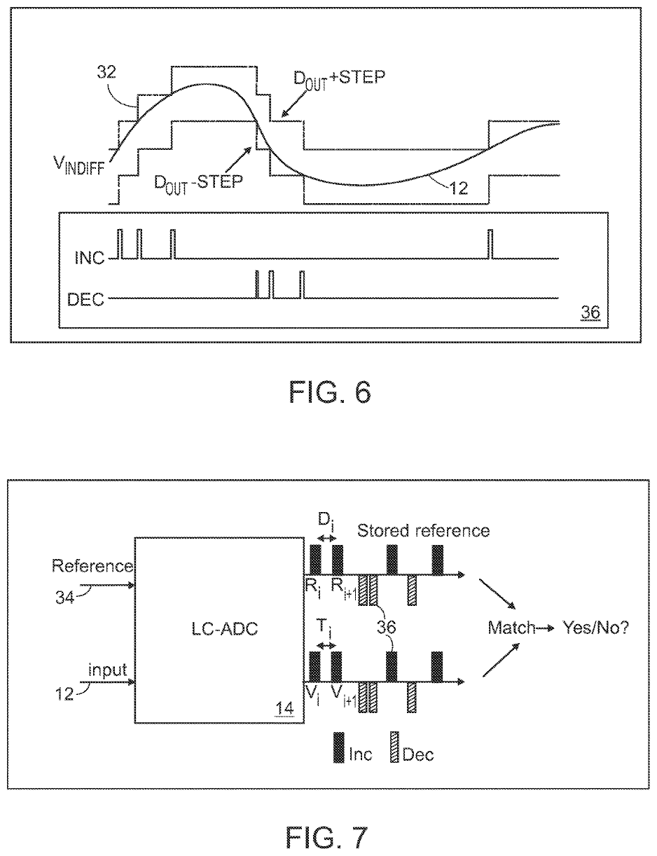

FIG. 6 shows the guiding signal 32 as it appears when incremented or decremented by the step. The input signal 12 can be seen in between the two guiding signals 32. As shown below, an activity token of appropriate polarity is generated depending on the sign of the slope of the input signal 12 at the time it crosses a quantization level.

The level-crossing analog-to-digital converter 14 digitizes by monitoring the time instants at which the input signal 12 crosses the pre-defined quantization levels. Continuous time comparators 24, 26, shown in FIG. 5, record these quantization-level crossings. The time between quantization-level crossings is measured using a counter or a time-to-digital converter 34.

Since the digital-to-analog converter 30 only needs to increment or to decrement by the relevant step, it can easily be implemented in a manner similar to a charge pump. The digital-to-analog converter 30 need not be all that precise. After all, the quantization levels are known a priori and are therefore available for signal reconstruction. In addition, they would be the same for both the input signal 12 and any reference waveform used for correlation.

The output of the level-crossing analog-to-digital converter 14 is a continuous-time digital bit stream of activity tokens 36 of both types. Information about the input signal 12 comes from the timing between these activity tokens 36 and the quantization levels being crossed. The time-to-digital converter 34 is therefore particular useful for reconstructing the input signal 12.

In some cases, the size of the step depends on the value that corresponds to the least-significant bit. In such cases, the comparators 26, 28 track whether the signal is within that value around a previously crossed level and generate either an increment or decrement token as required, as shown by the example in FIG. 6.

FIG. 7 shows the platform 10 of FIG. 1 being used to look for correlation between an input signal 12 and a reference waveform 34. In this application, signal reconstruction is unnecessary. Instead, one monitors the sequence of activity tokens 36 resulting from the input signal 12 and compares it with a sequence of activity tokens 26 that would have resulted from the reference waveform 34.

Correlation in this case is a simple operation of template matching, i.e. comparing the order and timing of the activity tokens 36 arising from tracking the input signal 12 and those that would have arisen had the reference waveform 34 been the input signal 12. No signal reconstruction is necessary.

Since the reference waveform 34 is pre-defined and not the result of measurement, any background noise resulting in timing jitter only affects the input signal 12.

In addition, for those cases in which the level-crossing analog-to-digital converter 14 that adapts quantization levels based on slope, any differences in scale between the reference waveform and input signal 12 will be accounted for.

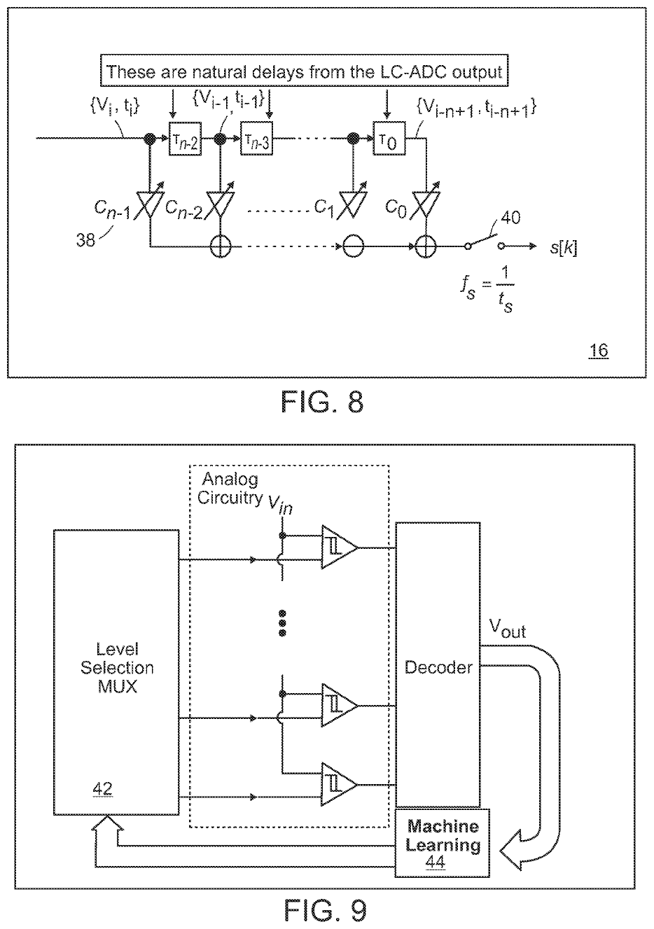

If needed, the matched filter 16 can be implemented to directly process increment/decrement event streams. A suitable matched filter 16 comprises an asynchronous analog delay line filter 38, as shown in FIG. 8. A sampler 40 samples the output of the delay line filter 38 and provides the resulting samples to the signal-processing circuitry 18 for feature extraction.

The total number of delay taps shown in the filter 16 depends on the length of the correlator and expected system dynamic range improvement. Although analog delays are non-uniform and not integer multiples of a clock period, it is possible to estimate that 1024 delay taps will be equivalent to correlator length of 65,536 to match a 1~3 GHz chirp signal waveform.

This would be expected to increase system dynamic range by 30~50 dB for total dynamic range 90~120 dB.

A particularly useful feature of the filter 16 is that the signals amount to increments and decrements of equal magnitude. Thus, only simple summation is carried out. There is no complex multiplication or accumulation operation needed. This tends to reduce power consumption.

The embodiment shown in FIG. 3 moves the function of template matching and matched filtering to dynamic variation of the quantization levels in a way that matches the reference waveform 34. Referring to FIG. 9, the embodiment shown in FIG. 3 features a flash-like level-crossing analog-to-digital converter 14 with level selection logic driven 42 by a machine learning engine 44. The selected quantization level is then provided to a decoder 46.

In effect, the act of varying quantization levels amounts to selecting different comparators for recording time stamps of a corresponding crossing of a quantization level crossing. A lightweight machine-learning engine 44 will perform this task.

As discussed in connection with the embodiment of FIG. 1, the sequence of comparator firings, each of which corresponds to a crossing of a quantization level, is matched to that of a reference sequence for a matching template waveform. This can be achieved using an analog delay line filter 38 like that described in connection with FIG. 8.

A simpler approach is to set the comparators, and hence the quantization levels, based on the template waveform, to cause periodic generation of activity tokens 36. This avoids the need to capture timing information. A simple task thereafter is to match this sequence with that of the template waveform. This avoids the need to prepare a delay cell and an analog delay line matched filter 38 as discussed in the embodiment of FIG. 1.

Template matching can be performed using logic gates. This avoids the need for a state machine, thereby considerably simplifying the architecture. It is also possible, using the foregoing architecture, to perform template matching for multiple templates in parallel with the same front end.

Embodiments include those that carry out correlation between the input signal 12 and another signal based on the activity tokens 36. One method for doing so is to extend each activity token 36 by a fixed width, and to then measure the extent to which activity tokens overlap. A simple way to do this is to integrate over time.

Another method for carrying out correlation is to cause an event of known duration upon arrival of a token 36 and to see if another token 36 arrives before the event is complete. A useful event that is easily reproducible is an RC discharge. This is similar to looking for overlap between extended activity tokens 36 except that the overlap is now between a token and an event that is essentially a stand-in for an extended activity token 36. Comparing the number of such overlaps with a threshold provides a basis for determining correlation.

Yet another method is to simply provide activity tokens 36 as inputs to a logic gate, such as an “AND” gate or an “XOR” gate, and to then see if an overlap exists. This method is simple to implement but somewhat less accurate than the foregoing methods.

The omission of both an anti-aliasing filter for an inbound signal and a matched filter for an outbound signal results in an overall lean architecture. The machine learning engine 20 can be programmed to choose the comparators (and thus the quantization levels, optimally and not merely to match the template waveform. In addition, the selection of quantization levels can be carried out adaptively in real time to accommodate varying signal conditions such as signal strength and background interference and noise levels. In effect, the machine-learning engine 20 carries out embedded correlation with embedded delay line filtering, programmable gain amplification, and signal filtering with timely selections of quantization levels.

The data-acquisition platform 10 is useful for numerous applications. Among these applications is that of carrying out analog cross-correlation. Also among the applications are those that include identifying particular features in signals, such as the QRS complex in an electrocardiogram or detecting the existence of subtle signals, such as ultra wideband signals, radar signals, or jamming from a background of many other wireless signals.

In addition, the platform 10 is useful for sensing and measurement of faint and weak signals, such as those that arise in remote sensing. The signals that the platform 10 operates on are not limited to electromagnetic signals.

The platform 10 operates equally well for carrying out similar functions using ultrasonic signals or acoustic signals. In addition, it is applicable for use with shorter-wavelength electromagnetic signals, such as those used in laser-based instrumentation and metrology.

The foregoing applications are carried out by suitable training of the machine-learning engine 44 on identifying features that distinguish those signals.

Based on the times at which activity tokens 36 occur, it is possible to infer that the input signal 11 crossed a particular value at a particular time as well as to infer the rate of change of the input signal 12. Therefore, based on the times between activity tokens 36, it is possible to provide a reasonably accurate reconstruction of the original input signal 12.

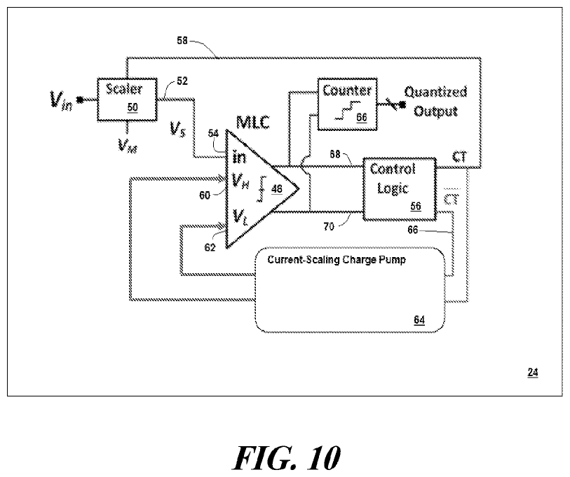

In addition, the times between activity tokens 36 also provide a basis for determining a temporal density of activity tokens 36, which in turn provides a basis for dynamically adjusting a window that defines a quantization level. FIG. 10 shows an alternative embodiment of a token generator 24 that uses the variable token frequency as a basis for dynamically adjusting the upper and lower bounds of such a window.

The token generator 24 relies on a multi-level comparator 48 that receives an input from a scaler 50. The scaler 50 receives the input signal 12 and scales it by a factor that depends on the upper of the two bounds, thus producing a scaled input 52 that is ultimately provided to a first input 54 of the multi-level comparator 48. Control logic 56 receives this dynamically changing upper level and uses it to provide a first control-signal 58 that controls the extent to which the scaler 50 scales the input signal 12.

Second and third inputs 60, 62 of the multi-level comparator 48 receive upper and lower levels from a current-scaling charge pump 64. These upper and lower levels represent the time-varying bounds that define a window that grows larger or smaller, as if it were breathing. The control logic 56 controls the upper and lower bounds using the first control-signal 58 and a second control-signal 66, the latter simply being the complement of the first control-signal 58.

The multi-level comparator 48 includes a first output 68 that indicates when the scaled input 52 exceeds the window's current upper bound of the window and a second output 70 that indicates when the scaled input 52 falls below the window's current lower bound. These correspond to the generation of activity tokens 36 of opposite polarities. The first and second outputs 68, 70 are then provided to a counter 72 that provides data for use in reconstructing the analog input signal 12. They are also provided to the control logic 56, which uses them as a basis for outputting its first and second control-signals 58, 66, thereby dynamically adjusting the window's bounds.

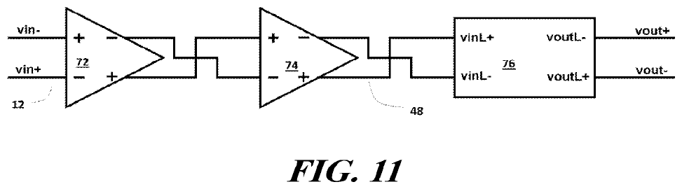

FIG. 11 discloses a low-power implementation of a multi-level comparator 48 that comprises first pre-amplifier 72 that receives a rail-to-rail input voltage and provides its output to the inputs of a second pre-amplifier 74. The output of the second pre-amplifier 74 is then provided to a cross-coupled latch 76.

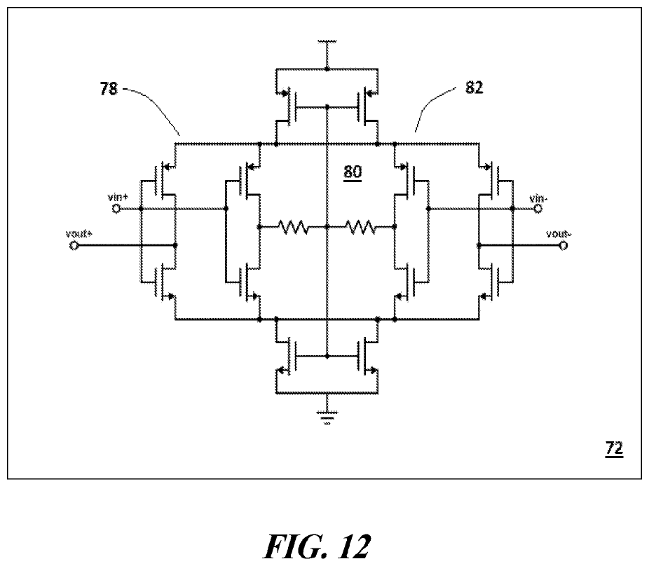

FIG. 12 shows details of the first pre-amplifier 72. The second pre-amplifier 74 is of identical design. The first pre-amplifier 72 includes first and second inverters 78, 80 with biasing circuitry 82 therebetween. Each inverter 72, 80 uses a P-channel and an N-channel MOSFET to simplify the process of accommodating the rail-to-rail voltage. These inverters 78, 80 are being used as amplifiers rather than as digital circuits that invert inputs thereof.

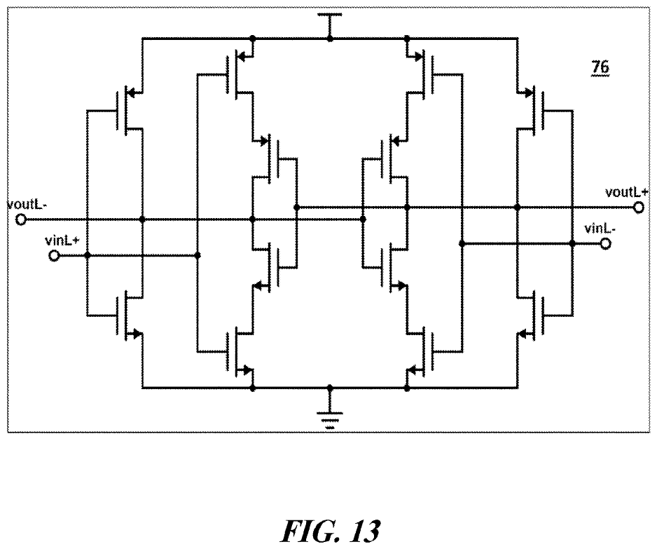

FIG. 13 shows details of the cross-coupled latch 76 shown in FIG. 11.

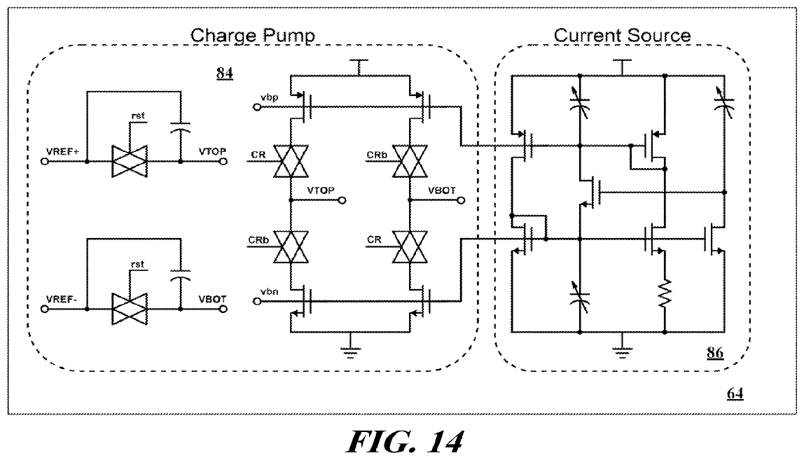

FIG. 14 shows details of the current scaling charge pump 64 of FIG. 10 with its charge-pump circuitry 84 coupled to a current source 86.

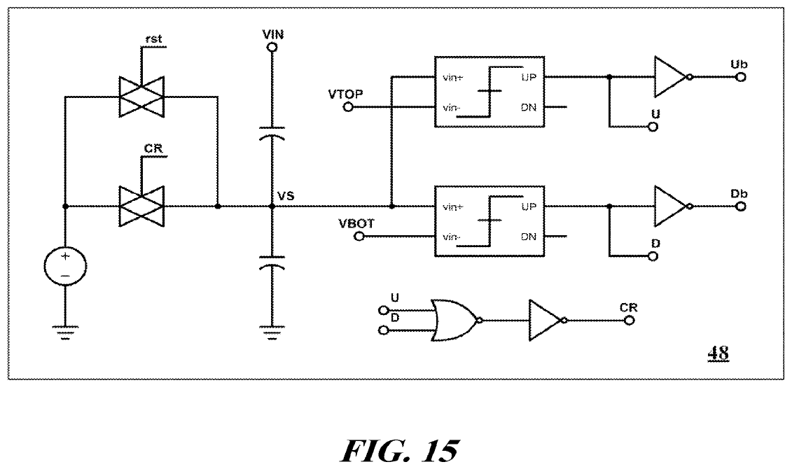

FIG. 15 shows details of the comparator 48 shown in FIG. 10.

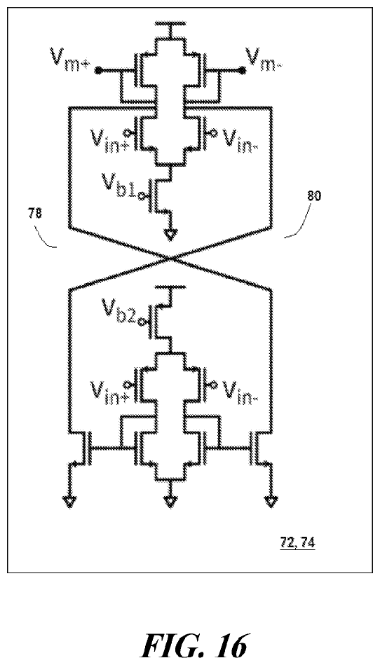

FIG. 16 shows details of an alternative embodiment of the first and second preamplifiers 72, 74 showing the first and second inverters 78, 80 connected in parallel. As was the case with FIG. 12, each inverter 78, 80 uses a P-channel MOSFET and an N-channel MOSFET.

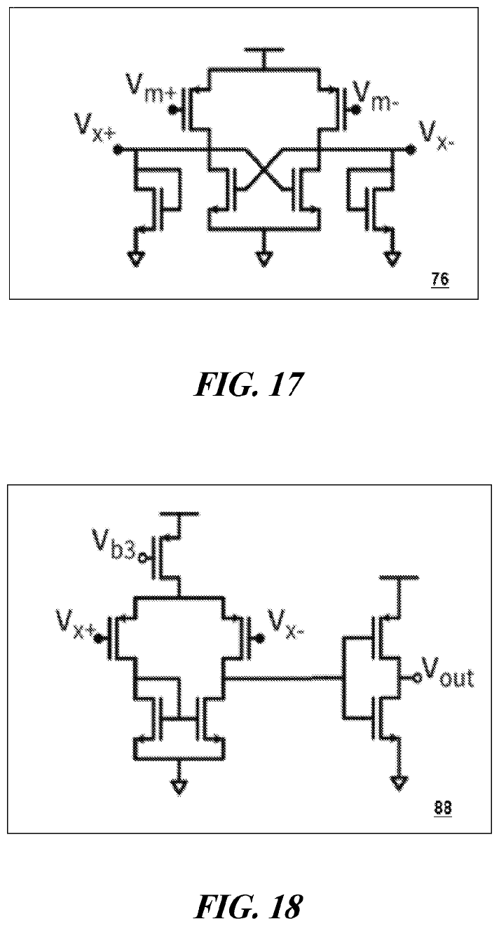

FIG. 17 shows details of another embodiment of a cross-coupled latch 76.

FIG. 18 shows a third amplifier 88 to be used in an embodiment similar to that shown in FIG. 11 but with the output of the second amplifier 74 being provided to the third amplifier 88. In such an embodiment, the output of the third amplifier 88 is provided to the cross-coupled latch 76.

Having described the invention and a preferred embodiment thereof, what is claimed as new and secured by letters patent is:

1. An apparatus comprising a data-acquisition platform that receives an input signal, said input signal being an analog input signal, said data-acquisition platform comprising a converter that provides activity tokens and circuitry connected to receive said activity tokens from said converter, wherein said converter comprises a level-crossing analog-to-digital converter that generates an activity token when said input signal crosses a quantization level, wherein said circuitry is selected from the group consisting of: a filter, said filter comprising a delay-line analog filter configured to cause said converter to adaptively change said quantization levels and an adaptation module configured to cause said converter to adaptively change said quantization levels.

2. The apparatus of claim 1, wherein said circuitry comprises said filter.

3. The apparatus of claim 1, wherein said circuitry comprises said adaptation module.

4. The apparatus of claim 1, wherein said converter comprises a first comparator and a second comparator, wherein said first comparator generates a first activity token upon detecting that said input signal has crossed a first quantization level, wherein said second comparator generates a second activity token upon detecting that said input signal has crossed a second quantization level, and wherein said first and second activity tokens have opposite polarity.

5. The apparatus of claim 1, further comprising correlation circuitry that determines, based on said activity tokens, whether said input signal matches a reference signal.

6. The apparatus of claim 1, further comprising correlation circuitry that uses said activity tokens to carry out analog cross-correlation between said input signal and another signal.

7. The apparatus of claim 1, wherein said input signal is an electrocardiogram signal and wherein said data-acquisition platform is configured to identify a QRS complex in said electrocardiogram signal.

8. The apparatus of claim 1, wherein said input signal comprises a combination of plural wireless signals and wherein said data-acquisition platform is configured to identify said input signal as being an ultra-wideband signal in said combination.

9. The apparatus of claim 1, wherein said input signal comprises a combination of plural wireless signals and wherein said data-acquisition platform is configured to identify said input signal as being a jamming signal in said combination.

10. The apparatus of claim 1, wherein said input signal comprises a combination of plural wireless signals and wherein said data-acquisition platform is configured to identify said input signal as being a radar signal in said combination.

11. The apparatus of claim 1, wherein said input signal comprises an ultrasonic signal and wherein said data-acquisition platform is configured to identify features in said ultrasonic signal.

12. The apparatus of claim 1, wherein said input signal is an electrocardiogram signal and wherein said data-acquisition platform is configured to identify an arrhythmia in said electrocardiogram signal.

13. The apparatus of claim 1, wherein said input signal is a combination of acoustic signals and said data-acquisition platform is configured to identify a particular speaker of one of said acoustic signals.

14. The apparatus of claim 1, wherein said circuitry comprises said filter and wherein said filter comprises a matched filter.

15. The apparatus of claim 1, wherein said circuitry comprises said filter and wherein said filter comprises analog delay elements that are tunable.

16. The apparatus of claim 1, wherein said level-crossing analog-to-digital converter is configured to sample said input signal at a rate that is controlled by said input signal.

17. A method comprising receiving an analog input signal, adaptively changing at least one quantization level of a level-crossing analog-to-digital converter, generating an activity token when said input signal crosses said quantization level, and receiving said activity token, wherein adaptively changing said at least one quantization level comprises using a circuit selected from the group consisting of a delay-line analog filter and an adaptation module.

18. The method of claim 17, further comprising sampling said analog input signal at a sampling rate that is controlled by said analog input signal.

19. The method of claim 17, wherein adaptively changing said quantization level comprises adaptively changing said quantization level based on carrying out real-time adjustment of said quantization levels based on background noise and based on a property of said analog input signal.

20. The method of claim 17, wherein adaptively changing said at least one quantization level comprises causing said quantization levels of said level-crossing analog-to-digital converter be time-varying quantization levels.
